(19) United States
(12) Patent Application Publication
(10) Pub. No.: US 2026/0011586 A1
(43) Pub. Date: Jan. 8, 2026

(54) SUBSTRATE PROCESSING APPARATUS AND METHOD OF OPERATING THE SAME

(71) Applicant: Samsung Electronics Co., Ltd., Suwon-si (KR)

(72) Inventors: CHANGBEA PARK, Suwon-si (KR); KI-IL KIM, Suwon-si (KR); SANGJUN OH, Suwon-si (KR); JISOO OH, Suwon-si (KR); KYUNGYUB JEON, Suwon-si (KR); YONGJOON CHEONG, Suwon-si (KR)

(21) Appl. No.: 19/066,283

(22) Filed: Feb. 28, 2025

(30) Foreign Application Priority Data
Jul. 4, 2024 (KR) 10-2024-0088466

(51) Int. Cl. H01L 21/67; G01B 11/06; G01J 3/42; G01N 21/88; H01L 21/66

(52) U.S. Cl. CPC H01L 21/67253; G01B 11/0625; G01J 3/42; G01N 21/8806; H01L 22/12

(57) ABSTRACT

A substrate processing apparatus includes a chamber having a first port and a second port, a stage disposed inside the chamber and configured to support a substrate, a first light emitting system configured to radiate a first incident light through the first port onto the substrate when disposed inside the chamber, a second light emitting system configured to radiate a second incident light through the second port onto an inner surface of a wall of the chamber, and a spectrometer configured to receive a substrate-reflected light reflected from the substrate and a wall-reflected light reflected from the inner surface of the wall of the chamber.

### CROSS-REFERENCE TO RELATED APPLICATION(S)

This U.S. non-provisional application claims priority under 35 USC § 119 to Korean Patent Application No. 10-2024-0088466, filed on Jul. 4, 2024, in the Korean Intellectual Property Office, the disclosure of which is herein incorporated by reference in its entirety.

### BACKGROUND

Example embodiments relate to a substrate processing apparatus and a method of operating the same, and more particularly, to a substrate processing apparatus for measuring thicknesses of layers formed within a chamber and a method of operating the same.

Semiconductor devices are manufactured through various processes. During at least one of these processes, walls of a chamber may be damaged or contained by process products adhering thereto. This may significantly disrupt constancy within the chamber, leading to defects in the semiconductor devices. Accordingly, there is ongoing research into various methods for significantly reducing damage to the chamber or contamination caused by process byproducts.

### SUMMARY

Example embodiments provide a substrate processing apparatus with improved performance of maintaining consistency within a chamber and a method of operating the same.

Example embodiments provide a substrate processing apparatus for monitoring a state within a chamber and a method of operating the same.

Example embodiments provide a substrate processing apparatus for monitoring thicknesses of layers and a method of operating the same.

According to an example embodiment, a substrate processing apparatus includes a chamber having a first port and a second port, a stage disposed inside the chamber and configured to support a substrate, a first light emitting system configured to radiate a first incident light through the first port onto the substrate when disposed inside the chamber, a second light emitting system configured to radiate a second incident light through the second port onto an inner surface of a wall of the chamber, and a spectrometer configured to receive a substrate-reflected light reflected from the substrate and a wall-reflected light reflected from the inner surface of the wall of the chamber.

According to an example embodiment, a method of operating a substrate processing apparatus includes placing a substrate on a stage inside a chamber, performing a manufacturing process on the substrate, radiating a first portion of a first light onto the substrate through a first port of the chamber by a first light emitting system, radiating a second portion of a second light onto an inner surface of a wall of the chamber through a second port of the chamber by a second light emitting system, receiving a substrate-reflected light reflected from the substrate and a wall-reflected light reflected from the inner surface of the wall by a spectrometer, and generating a thickness of a measurement target layer of the substrate and a thickness of a chamber protective layer on an inner surface of the wall based on the substrate-reflected light and wall reflected lights.

### BRIEF DESCRIPTION OF DRAWINGS

FIG. 1 is a diagram illustrating a substrate processing apparatus according to an example embodiment.

FIG. 2 is an enlarged view of region S1 of FIG. 1.

FIG. 3 is an enlarged view of region S2 of FIG. 1.

FIG. 4 is a graph illustrating thicknesses of layers calculated by Fourier transform from complex data.

FIG. 5 is a diagram illustrating a substrate processing apparatus according to an example embodiment.

FIG. 6 is a flowchart illustrating a method of operating a substrate processing apparatus according to an example embodiment.

FIGS. 7, 9, 11, and 14 are drawings illustrating a method of operating a substrate processing apparatus according to an example embodiment.

FIG. 8 is an enlarged view of region S3 of FIG. 7.

FIG. 10 is an enlarged view of region S4 of FIG. 9.

FIG. 12 is an enlarged view of region S5 of FIG. 11.

FIG. 13 is an enlarged view of region S6 of FIG. 11.

FIG. 15 is an enlarged view of region S7 of FIG. 14.

FIG. 16 is a diagram illustrating a substrate processing apparatus according to an example embodiment.

FIG. 17 is an enlarged view of region S8 of FIG. 16.

### DETAILED DESCRIPTION

Hereinafter, example embodiments will be described with reference to the accompanying drawings.

The invention may be embodied in many different forms and should not be construed as limited to the example embodiments set forth herein. These example embodiments are just that—examples—and many implementations and variations are possible that do not require the details provided herein. The disclosure provides details of alternative examples, but such listing of alternatives is not exhaustive.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise.

It will be understood that, although the terms first, second, third, fourth etc. may be used herein to describe various elements, components, ports, light emitting systems, light, splitters, reflectors, materials, etc., these elements, components, ports, light emitting systems, light, splitters, reflectors, materials, etc. should not be limited by these terms. Unless the context indicates otherwise, these terms are only used to distinguish one element, component, port, light emitting system, light, splitter, reflector, material, etc., from another element, component, port, light emitting system, light, splitter, reflector, material, etc., for example as a naming convention.

Spatially relative terms, such as “above,” “upper,” “up”, “bottom,” “down”, “rear,” “right”, “left”, “vertical”, “horizontal” and the like, may be used herein for ease of description to describe positional relationships, such as illustrated in the figures, for example. It will be understood that the spatially relative terms encompass different orientations, in addition to the orientation depicted in the figures.

The characters ‘U’ (up), ‘D’ (down), ‘Le’ (left), and ‘Ri’ (right) in the figures, are used for ease of description to indicate directions. However, the technical scope of the specification is not limited to the above characters.

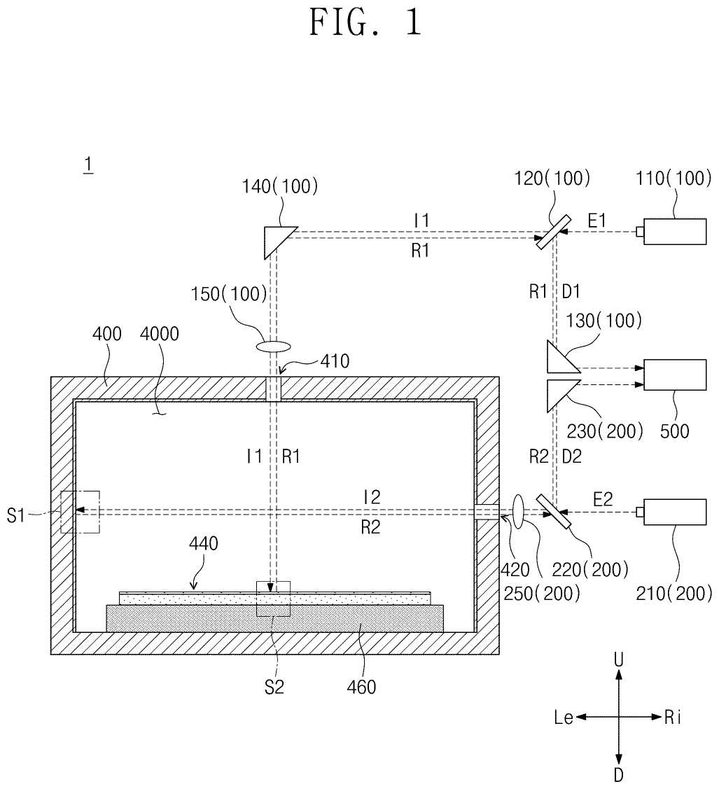

FIG. 1 is a diagram illustrating a substrate processing apparatus 1 according to an example embodiment.

Referring to FIG. 1, embodiments of the substrate processing apparatus 1 will be described. The substrate processing apparatus 1 may perform a manufacturing process on a substrate 440. For example, the manufacturing process may be an etching process or a deposition process. For example, the substrate processing apparatus 1 may be an etching apparatus performing an etching process on the substrate 440, or a deposition apparatus performing a deposition process on the substrate 440.

The substrate processing apparatus 1 may include a chamber 400 in which a processing space 4000 is defined. The substrate 440 may be processed within the processing space 4000. The chamber 400 may isolate the processing space 4000 from an external environment. A vacuum environment may be established in the processing space 4000. For example, the substrate processing apparatus 1 may perform a manufacturing process (for example, an etching process) on the substrate 440 in the processing space 4000 in which the vacuum environment is established.

The chamber 400 may include a wall, a ceiling, and a floor that define the processing space 4000. The wall, the ceiling, and the floor may surround the processing space 4000.

The chamber 400 may have ports. Each of the ports may be formed in one of the wall, the ceiling, and the floor of the chamber 4000. The ports may be for example, windows. For example, the ports may optically connect the processing space 4000 of the chamber 400 and the external environment. However, the ports may physically isolate the processing space 4000 of the chamber 400 from the external environment. For example, the ports may not allow communication between the processing space 4000 of the chamber 400 and the external environment. Thus, the processing space 4000 of the chamber 400 may be maintained in a vacuum environment during the manufacturing process.

In an example embodiment, the ports may include a first port 410 and a second port 420. According to an example embodiment, the first port 410 may be formed in the ceiling of the chamber 400. According to an example embodiment, the second port 420 may be formed in a single wall of the chamber 400.

The substrate processing apparatus 1 may further include a stage 460 configured to support the substrate 440. The stage 460 may include an electrostatic chuck (ESC) fixing and supporting the substrate 440 using electrostatic force. The stage 460 may be disposed in the chamber 400. For example, the stage 460 may be disposed in the processing space 4000. For example, the substrate 440 may be loaded on the stage 460, and the manufacturing process may be performed on the substrate 440 on the stage 460.

The substrate processing apparatus 1 may include light emitting systems configured to radiate light. The light emitting systems may be disposed outside the chamber 400. Each of the light emitting systems may be configured to radiate light into the chamber 400 (for example, into the processing space 4000) through a corresponding one of the ports. In some embodiments, each of the light emitting systems may be configured to radiate light onto an internal surface of the wall of the chamber 400 or onto the substrate 440 when disposed on the stage 460 through a corresponding port.

The substrate processing apparatus 1 may further include a spectrometer 500 configured to receive light, for example from multiple sources. The spectrometer 500 may be configured to receive and analyze light. In an example embodiment, the spectrometer 500 may measure the intensity of the received light based on a wavelength. For example, the spectrometer 500 may receive a plurality of lights and decompose and measure complex data obtained from the received lights.

The spectrometer 500 may be configured to receive light reflected within the chamber 400. For example, the spectrometer 500 may be configured to receive reflected lights, emitted from the chamber 400, through the first and second ports 410 and 420. In addition, the spectrometer 500 may be configured to receive a portion of the light emitted from each of the light emitting systems. For example, the spectrometer 500 may be configured to receive light branched from each of the light emitting systems (for example, split light discussed herein).

The light emitting systems may include a first light emitting system 100 configured to radiate light through the first port 410 and a second light emitting system 200 configured to radiate light through the second port 420. The first light emitting system 100 may be configured to radiate first incident light I1 onto the substrate 440 when disposed in the chamber 400. For example, the first light emitting system 100 may be configured to radiate the first incident light I1 perpendicularly onto the substrate 440 when disposed on the stage 460. The first port 410 may be disposed over the stage 460.

The first light emitting system 100 may include a first light source 110 configured to emit first light E1 and a first splitter 120 configured to split the first light E1. The first splitter 120 may split the first light E1 into a plurality of lights. For example, the first splitter 120 may split a first light E1 into the first incident light I1 incident on the first port 410 and a first split light D1 incident on the spectrometer 500.

The first light emitting system 100 may further include a first reflector 130 configured to guide the first split light D1 to the spectrometer 500. The first reflector 130 may be configured to redirect a propagation path of the first split light D1 emitted from the first splitter 120. For example, the first reflector 130 may be a mirror that may reflect the first split light D1, emitted from the first splitter 120, to the spectrometer 500.

The first light emitting system 100 may further include an auxiliary reflector 140 configured to guide the first incident light I1 to the first port 410. The auxiliary reflector 140 may be configured to redirect a propagation path of the first incident light I1 emitted from the first splitter 120. For example, the auxiliary reflector 140 may be a mirror that may reflect the first incident light I1, emitted from the first splitter 120, to the first port 410.

The first light emitting system 100 may further include a first condensing lens 150 condensing the first incident light I1 incident on the first port 410. The illuminance of the first incident light I1, incident on the first port 410, may be increased due to the first condensing lens 150. The first condensing lens 150 may be disposed between the first splitter 120 and the first port 410. For example, the first condensing lens 150 may be disposed between the auxiliary reflector 140 and the first port 410.

The first light E1 may be emitted from the first light source 110. The first light E1 may pass through the first splitter 120. The first splitter 120 may split the first light E1 into the first incident light I1 and the first split light D1. The auxiliary reflector 140 may guide the first incident light I1 to the first port 410. Thus, the first incident light I1 may be directed to the first port 410. The first condensing lens 150 may condense the first incident light I1 emitted from the auxiliary reflector 140. Thus, the first incident light I1 may be incident into the chamber 400 through the first port 410.

The first incident light I1 may be radiated to the substrate 440 through the first port 410. The first incident light I1 may be reflected by the substrate 440. The light reflected from the substrate 440 may be for example, substrate-reflected light R1 or first reflected light. Hereinafter, for ease of description, the light reflected from the substrate 440 may be referred to as substrate-reflected light R1.

The substrate-reflected light R1 may be emitted to outside the chamber 400 through the first port 410. The first condensing lens 150 may condense the substrate-reflected light R1 emitted through the first port 410. The auxiliary reflector 140 may guide the substrate-reflected light R1, emitted through the first condensing lens 150, to the first splitter 120. Thus, the substrate-reflected light R1 may be directed to the first splitter 120.

The first splitter 120 may redirect a propagation path of the substrate-reflected light R1. The first splitter 120 may guide the substrate-reflected light R1, emitted from the auxiliary reflector 140, to the first reflector 130. For example, the first splitter 120 may reflect the substrate-reflected light R1, emitted from the auxiliary reflector 140, to the first reflector 130. The first reflector 130 may guide the substrate-reflected light R1 to the spectrometer 500. For example, the first reflector 130 may reflect the substrate-reflected light R1 to the spectrometer 500. Thus, the substrate-reflected light R1 emitted from the first splitter 120 may be incident on the spectrometer 500. Also, as described herein, the first split light D1 may be incident on the spectrometer 500 by the first reflector 130.

The spectrometer 500 may receive lights reflected by the first reflector 130. For example, the spectrometer 500 may be configured to receive the substrate-reflected light R1 and the first split light D1.

The second light emitting system 200 may be configured to radiate the second incident light 12 onto an inner surface of the wall of the chamber 400. For example, the chamber 400 may include a first wall, in which the second port 420 is formed, and a second wall opposing the first wall, and the second light emitting system 200 may be configured to radiate the second incident light 12 onto an inner surface of the second wall of the chamber 400. For example, the second light emitting system 200 may radiate the second incident light 12 horizontally onto the inner surface of the second wall of the chamber 400. The second port 420 may be disposed for example, above the stage 460. The second port 420 may further be disposed above the substrate 440 when disposed on the stage 460.

The second light emitting system 200 may include a second light source 210, configured to emit second light E2, and a second splitter 220 configured to split the second light E2. The second splitter 220 may split the second light E2 into a plurality of lights. For example, the second splitter 220 may split the second light E2 into a second incident light 12 incident on the second port 420 and a second split light D2 incident on the spectrometer 500.

The second light emitting system 200 may further include a second reflector 230 configured to guide the second split light D2 to the spectrometer 500. The second reflector 230 may be configured to redirect a propagation path of the second split light D2 emitted from the second splitter 220. For example, the second reflector 230 may be a mirror that may reflect the second split light D2 to the spectrometer 500.

The second light emitting system 200 may further include a second condensing lens 250 condensing the second incident light 12 incident on the second port 420. The illuminance of the second incident light 12, incident on the second port 420, may be increased due to the second condensing lens 250. The second condensing lens 250 may be disposed between the second splitter 220 and the second port 420.

The second light E2 may be emitted from the second light source 210. The second light E2 may pass through the second splitter 220. The second splitter 220 may split the second light E2 into a second incident light 12 and a second split light D2. The second condensing lens 250 may condense the second incident light 12 emitted from the second splitter 220. The second incident light 12, which has passed through the second condensing lens 250, may be incident into the chamber 400 through the second port 420.

The second incident light 12 may be radiated to the inner surface of the second wall of the chamber 400 through the second port 420. The second incident light 12 may be reflected by the second wall of the chamber 400. The light reflected from the second wall of the chamber 400 may be for example, wall-reflected light R2 or second reflected light. Hereinafter, for ease of description, the light reflected from the second wall of the chamber 400 may be referred to for example, as wall-reflected light R2.

The wall-reflected light R2 may be emitted to outside the chamber 400 through the second port 420. The second condensing lens 250 may condense the wall-reflected light R2 emitted through the second port 420. The condensed wall-reflected light R2 may be incident on the second splitter 220. The second splitter 220 may redirect a propagation path of the wall-reflected light R2. The second splitter 220 may guide the wall-reflected light R2 to the second reflector 230. For example, the second splitter 220 may reflect the wall-reflected light R2 to the second reflector 230.

The second reflector 230 may guide the wall-reflected light R2 to the spectrometer 500. For example, the second reflector 230 may reflect the wall-reflected light R2 to the spectrometer 500. Thus, the wall-reflected light R2 emitted from the second splitter 220 may be incident on the spectrometer 500. Also, as described herein, the second split light D2 may be incident on the spectrometer 500 by the second reflector 230.

The spectrometer 500 may receive lights reflected by the second reflector 230. For example, the spectrometer 500 may be configured to receive the wall-reflected light R2 and the second split light D2.

The substrate processing apparatus 1 may further include a controller, not illustrated. Although not illustrated, a controller can include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the processing controller 1020 (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the controller can include antennas, network interfaces that provide wireless and/or wire line digital and/or analog interface to one or more networks over one or more network connections (not shown), a power source that provides an appropriate alternating current (AC) or direct current (DC) to power one or more components of the controller, and a bus that allows communication among the various disclosed components of the controller.

The controller may be electrically connected to the first light source 110, the second light source 210, the spectrometer 500, and the stage 460 to control the first light source 110, the second light source 210, the spectrometer 500, and the stage 460, to be in communication with these various components. For example, the controller may control operations of the first light source 110, operations of the second light source 210, operations of the spectrometer 500, and operations of the stage 460.

In the above-described embodiment, the first light emitting system 100 may include the first reflector 130 and the auxiliary reflector 140, and the second light emitting system 200 may include the second reflector 230. However, example embodiments are not limited thereto. In some embodiments, when at least one of the locations of the first light source 110 and the first port 410 is changed, the number of reflector(s) in the first light emitting system 100 may be variously changed to radiate the first incident light I1 to the first port 410 in consideration of the locations of the first light source 110 and the first port 410. Similarly, when at least one of the locations of the second light source 210 and the second port 420 is changed, the number of reflector(s) in the second light emitting system 200 may be variously changed to radiate the second incident light 12 to the second port 420 in consideration of the locations of the second light source 210 and the second port 420.

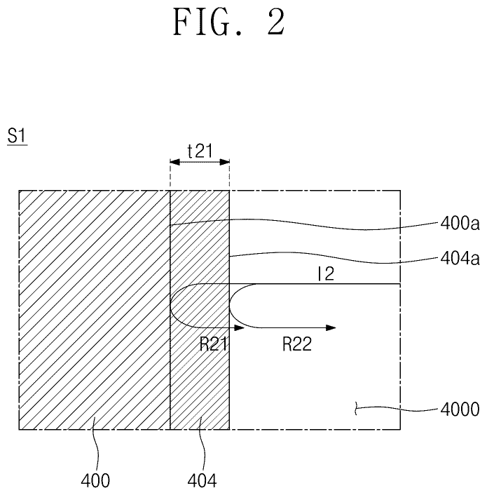

FIG. 2 is an enlarged view of region S1 of FIG. 1.

Referring to FIGS. 1 and 2, the wall-reflected light R2 reflected from the second wall of the chamber 400 will be described in more detail. The chamber 400 may include a chamber protective layer 404 covering an inner surface of the chamber 400. For example, the chamber protective layer 404 may also be disposed on the inner surface of the second wall of the chamber 400. The chamber protective layer 404 may be formed on the inner surface of the chamber 400, for example, by a coating method.

The chamber protective layer 404 may protect the inner surface of the chamber 400. The chamber protective layer 404 may be a material having improved durability. In addition, the chamber protective layer 404 may have light transmittance. A portion of the second incident light 12 may pass through the chamber protective layer 404. For example, the chamber protective layer 404 may be formed of or may consist of yttrium oxide (Y₂O₃).

The second incident light 12 may be radiated to the chamber protective layer 404 on the wall of the chamber 400. A portion of the second incident light 12 may pass through the chamber protective layer 404. The portion of the second incident light 12, which has passed through the chamber protective layer 404, may be reflected at an interface 400a between the wall of the chamber 400 and the chamber protective layer 404. The light reflected at the interface 400a between the wall and the chamber protective layer 404 may be for example, a first wall-reflected light R21.

The first wall-reflected light R21 may pass through the chamber protective layer 404, and may then be emitted into a processing space 4000. For example, the first wall-reflected light R21 may be reflected at the interface 400a between the wall of the chamber 400 and the chamber protective layer 404, and may then be emitted in a horizontal direction.

Another portion of the second incident light 12 may be reflected from a surface 404a of the chamber protective layer 404. The second portion of the second incident light 12 reflected from the surface 404a of the chamber protective layer 404 may be for example, a second wall-reflected light R22. The surface 404a of the chamber protective layer 404 may be directed to the inner space 4000. The second wall-reflected light R22 may be emitted from the surface 404a of the chamber protective layer 404 to the processing space 4000. For example, the second wall-reflected light R22 may be reflected from the surface 404a of the chamber protective layer 404, and may then be emitted in a horizontal direction. In embodiments having a further layer on the chamber protective layer 404 (described herein), the second wall-reflected light R22 may be emitted from an interface of the chamber protective layer 404 and the further layer, rather than being emitted from the surface 404a of the chamber protective layer 404.

The wall-reflected light R2 may include the first wall-reflected light R21 and the second wall-reflected light R22. Therefore, the spectrometer 500 may receive the first wall-reflected light R21 and the second wall-reflected light R22.

The spectrometer 500 may be configured to calculate a thickness of the chamber protective layer 404 based on the received light. For example, the spectrometer 500 may calculate the thickness of the chamber protective layer 404 based on the received first wall-reflected light R21, second wall-reflected light R22, and second split light D2.

Accordingly, the substrate processing apparatus 1 may monitor the thickness of the chamber protective layer 404. The substrate processing apparatus 1 may also monitor a change in the chamber 400, which may occur during a manufacturing process, in real time and provide information on the monitored change to an operator. In addition, the substrate processing apparatus 1 may measure a thickness of the chamber protective layer 404 remaining on the wall of the chamber 400, and provide information on a replacement cycle of parts to the operator. The term “parts” may refer to at least a portion of the chamber 400 in which the chamber protective layer 404 is formed. As a result, unnecessary waste of parts may be significantly reduced, costs of the manufacturing process may be reduced, and unnecessary manpower waste of operators may be reduced.

The thickness of a layer may refer to the dimension in the direction perpendicular to the surface of the layer.

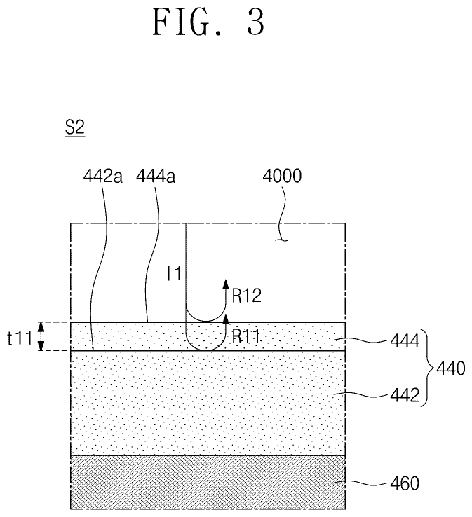

FIG. 3 is an enlarged view of region S2 of FIG. 1.

Referring to FIG. 3, the substrate 440 may include a base layer 442 and a measurement target layer 444. The base layer 442 may be a silicon wafer or a glass substrate. In an example embodiment, the base layer 442 may be a disk. For example, the base layer 442 may be a disk with a radius of 150 mm. However, example embodiments are not limited thereto, and a shape and/or a size of the base layer 442 may vary.

The measurement target layer 444 may be provided on the base layer 442. The measurement target layer 444 may be disposed on a surface 442a of the base layer 442. In an example embodiment, when the substrate processing apparatus 1 is an etching apparatus, the measurement target layer 444 may be an etching target layer formed in a previous manufacturing process. When the substrate processing apparatus 1 is a deposition apparatus, the measurement target layer 444 may be a deposition target layer to be formed by the manufacturing process performed in the chamber 400.

The first incident light I1 may be radiated to the substrate 440. The first incident light I1 may be radiated to the measurement target layer 444 on the base layer 442. A portion of the first incident light I1 may pass through the measurement target layer 444. The portion of the first incident light I1, which has passed through the measurement target layer 444, may be reflected at an interface 442a between the base layer 442 and the measurement target layer 444. As described herein, the interface 442a may be the surface 442a of the base layer 442. The light reflected at the interface 442a between the base layer 442 and the measurement target layer 444 may be for example, a first substrate-reflected light R11.

The first substrate-reflected light R11 may pass through the measurement target layer 444, and may then be emitted into the processing space 4000. For example, the first substrate-reflected light R11 may be reflected at the interface 442a between the base layer 442 and the measurement target layer 444, and may then be emitted in a vertical direction.

Another portion of the first incident light I1 may be reflected from the surface 444a of the measurement target layer 444. In an example embodiment, the surface 444a of the measurement target layer 444 may be an upper surface of the measurement target layer 444. The first portion of the first incident light I1 reflected from the surface 444a of the measurement target layer 444 may be for example, a second substrate-reflected light R12. The second substrate-reflected light R12 may be emitted from the surface 444a of the measurement target layer 444 to the processing space 4000. For example, the second substrate-reflected light R12 may be reflected from the surface 444a of the measurement target layer 444, and may then be emitted in a vertical direction.

The substrate-reflected light R1 may include a first substrate-reflected light R11 and a second substrate-reflected light R12. Therefore, the spectrometer 500 may receive the first substrate-reflected light R11 and the second substrate-reflected light R12.

The spectrometer 500 may be configured to calculate a thickness of the measurement target layer 444 based on the received light. For example, the spectrometer 500 may calculate the thickness of the measurement target layer 444 based on the received first substrate-reflected light R11, second substrate-reflected light R12, and first split light D1.

Accordingly, the substrate processing apparatus 1 may monitor the thickness of the measurement target layer 444. The substrate processing apparatus 1 may also monitor a change in the chamber 400, which has occurred during the process, in real time and provide information on the monitored change to the operator.

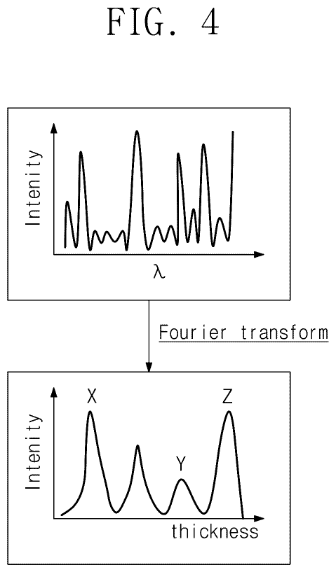

FIG. 4 is a graph illustrating thicknesses of layers calculated by Fourier transform from complex data (e.g., thickness measurement values may be generated by Fourier transform from complex data).

Referring to FIGS. 1 to 4, a mechanism for calculating thicknesses of layers in the chamber 400 will be described. The spectrometer 500 may obtain complex data including intensities depending on wavelengths of received lights. The received lights may include the first and second split lights D1 and D2, the substrate-reflected light R1, and the wall-reflected light R2. Therefore, the complex data may include intensities depending on wavelengths of the first and second split lights D1 and D2, intensities depending on wavelengths of the substrate-reflected light R1, and intensities depending on wavelengths of the wall-reflected light R2. The spectrometer 500 may represent the complex data as a spectrum graph (see an upper graph of FIG. 4).

The spectrometer 500 may perform a Fourier transform on the complex data. The transformed data (see a lower graph of FIG. 4) may include both information on the thickness of the layers measured by the first light emitting system 100 and information on the thickness of the layers measured by the second light emitting system 200. For example, the spectrometer 500 may analyze the transformed data to calculate thicknesses of a plurality of layers. Referring to the lower graph of FIG. 4, the transformed data illustrates a thickness of a first material X, a thickness of a second material Y, and a thickness of a third material Z. For example, the first material X may be a material of the measurement target layer 444, the second material Y may be a material of a passivation layer (for example, silicon dioxide (SiO₂)), and the third material Z may be a material of the chamber protective layer 404 (for example, yttrium oxide (Y₂O₃)).

As a result, the spectrometer 500 may simultaneously calculate the thickness of the measurement target layer 444 and the thickness of the chamber protective layer 404. In addition, the spectrometer 500 may monitor, in real time, a progress of the manufacturing process and an environmental change within the chamber 400 as the manufacturing process is performed. Moreover, changes in the chamber 400 that may occur during the manufacturing process may be monitored in real time, and information on the monitored changes may be provided to the operator.

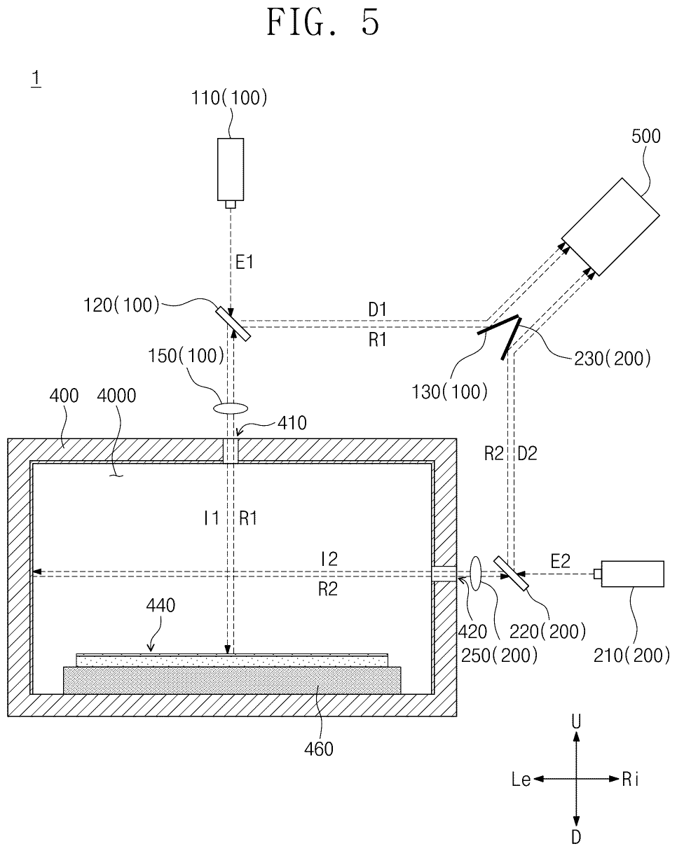

FIG. 5 is a diagram illustrating a substrate processing apparatus 1 according to an example embodiment.

Referring to FIG. 5, in the substrate processing apparatus 1 according to an example embodiment, a first light source 110 may be disposed above a first port 410. A first splitter 120 may be disposed between a first light source 110 and a first port 410. The first splitter 120 may split a first light E1, emitted from the first light source 110, into a first incident light I1 incident on the first port 410 and a first split light D1 incident on a spectrometer 500.

A first condensing lens 150 may be disposed between the first splitter 120 and the first port 410. The first incident light I1, emitted from the first splitter 120, may pass through the first condensing lens 150. The first incident light I1 may be incident into a chamber 400 through the first port 410.

The first split light D1, emitted from the first splitter 120, may be incident on the spectrometer 500. A first reflector 130 may guide the first split light D1 to the spectrometer 500. The first reflector 130 may redirect a propagation direction of the first split light D1 toward the spectrometer 500. According to the present embodiment, the auxiliary reflector 140 of FIG. 1 may be omitted.

Other components may be substantially the same as described with reference to FIG. 1.

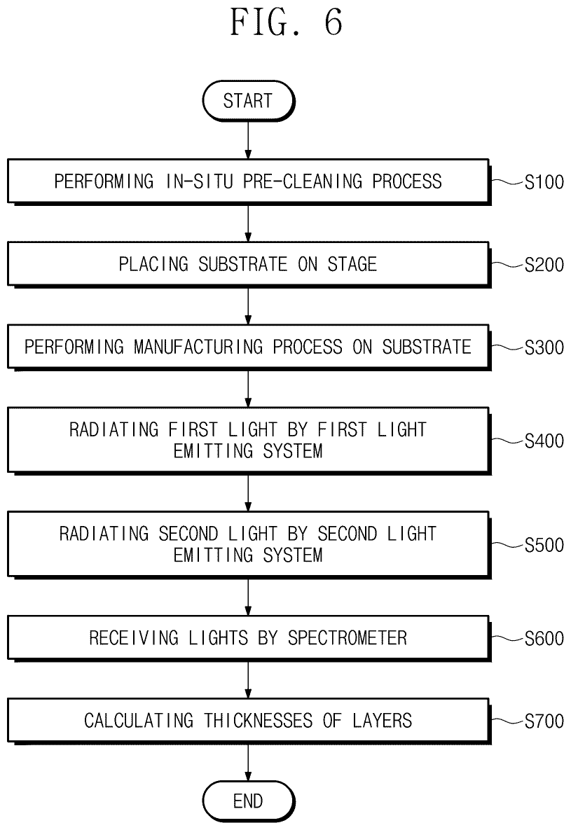

FIG. 6 is a flowchart illustrating a method of operating the substrate processing apparatus 1 according to an example embodiment.

Referring to FIG. 6, a method of operating the substrate processing apparatus 1 (which hereinafter may be referred to as an “operating method”) may include placing a substrate on a stage (S200), performing a manufacturing process on the substrate (S300), radiating first light by a first light emitting system (S400), radiating second light by a second light emitting system (S500), receiving light by a spectrometer (S600), and generating thicknesses of one or more layers (S700). In an example embodiment, the operating method may further include performing an in-situ pre-cleaning process (S100) before placing the substrate on the stage (S200).

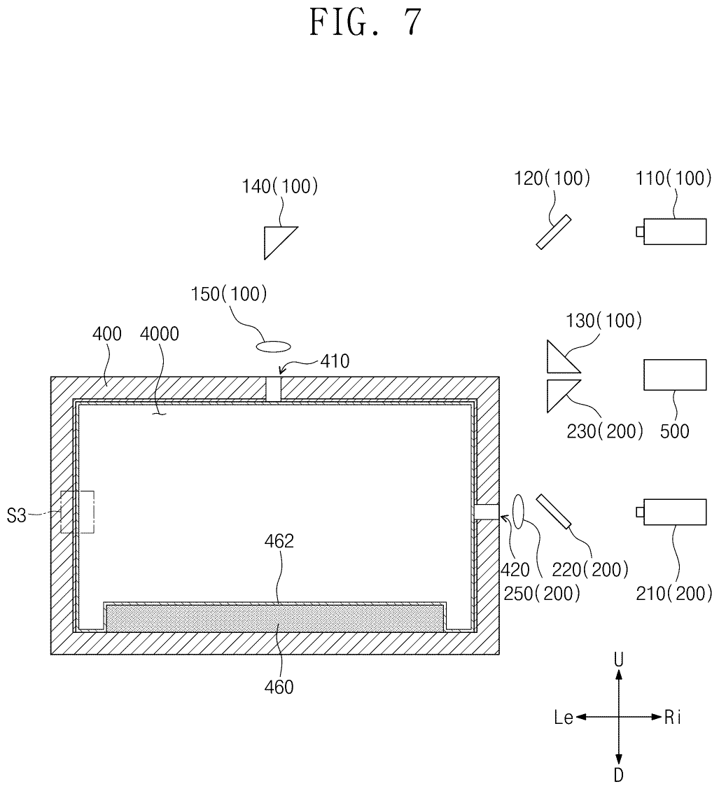

Hereinafter, the operating method will be described in more detail with reference to FIGS. 7 to 15.

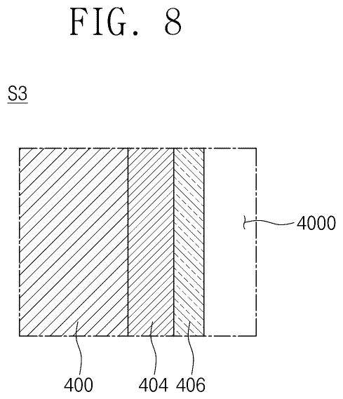

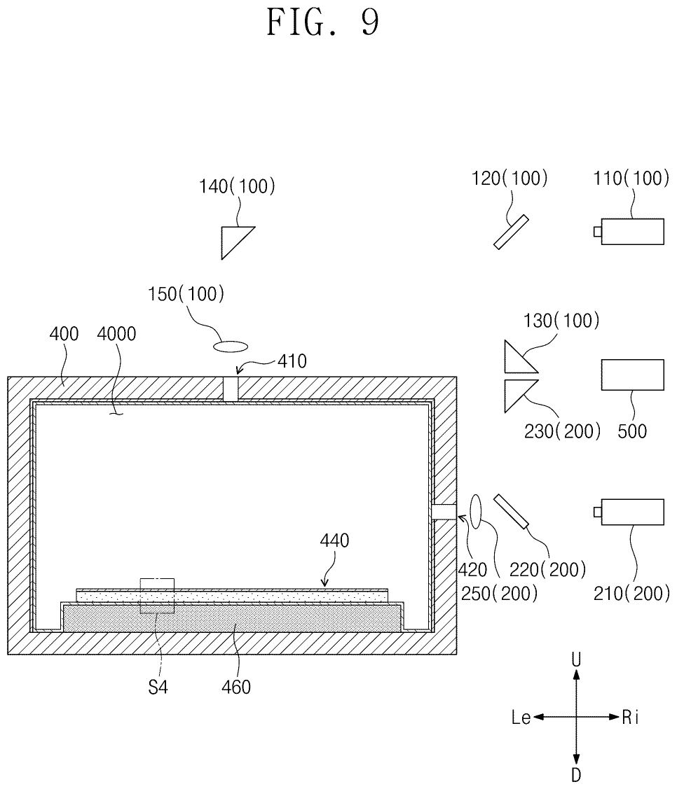

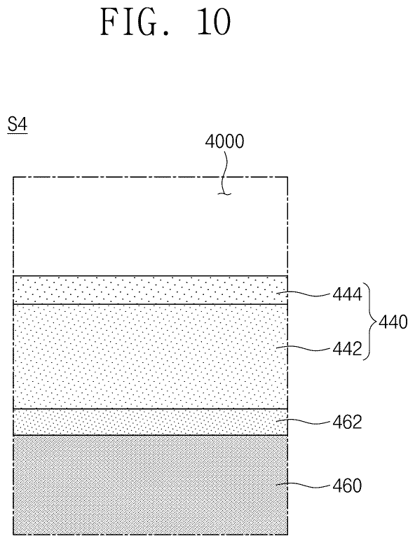

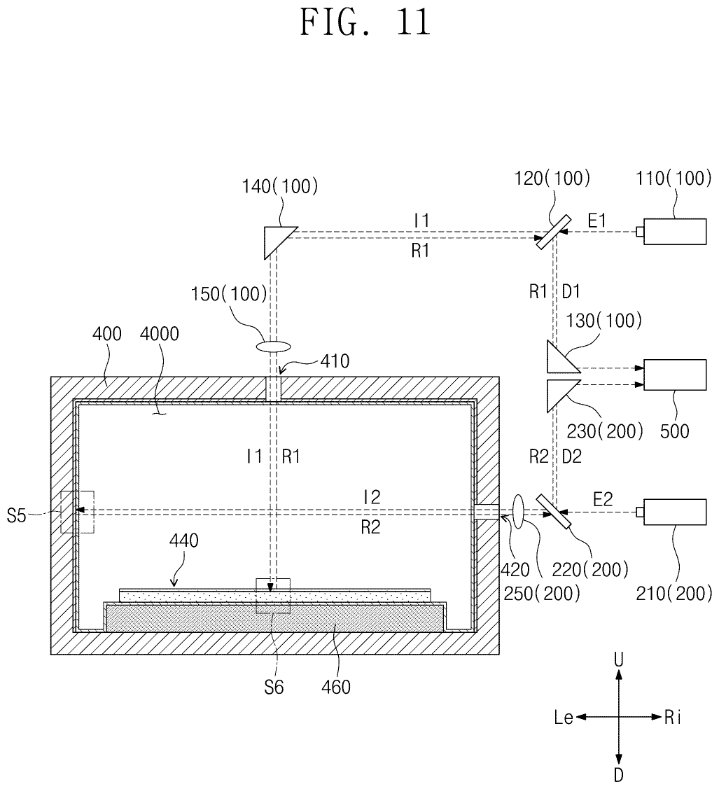

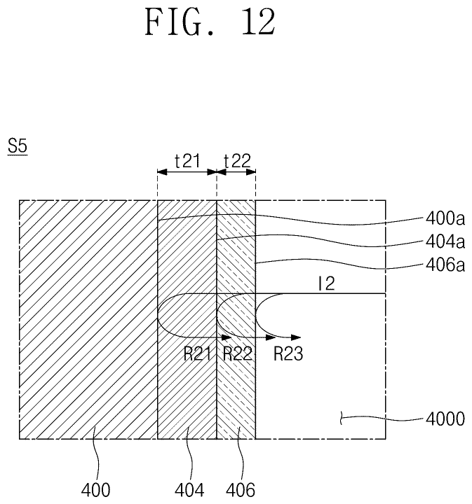

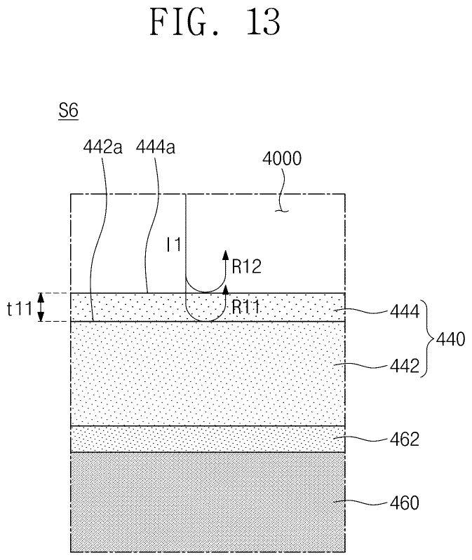

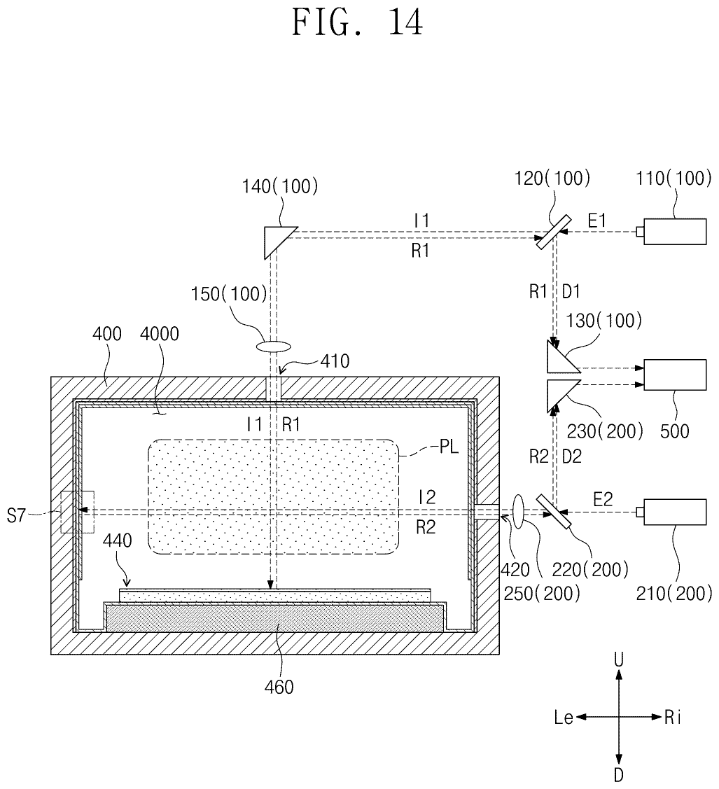

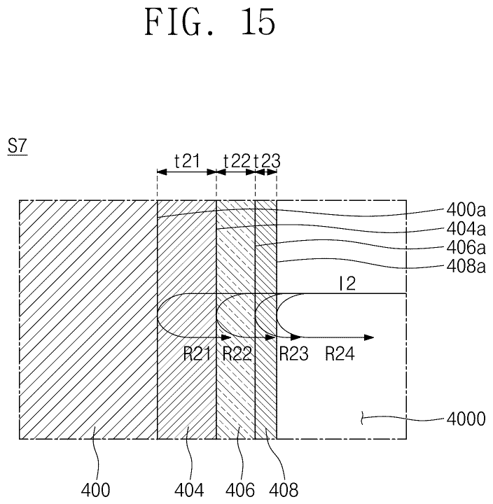

FIGS. 7, 9, 11, and 14 are diagrams illustrating a method of operating a substrate processing apparatus according to an example embodiment. FIG. 8 is an enlarged view of region S3 of FIG. 7. FIG. 10 is an enlarged view of region S4 of FIG. 9. FIG. 12 is an enlarged view of region S5 of FIG. 11. FIG. 13 is an enlarged view of region S6 of FIG. 11. FIG. 15 is an enlarged view of region S7 of FIG. 14.

Referring to FIGS. 6 to 8, the performing the in-situ pre-cleaning process (S100) may be preparation for performing the manufacturing process (S200). For example, the in-situ pre-cleaning process may be performed to clean the inside of the chamber 400 before performing the manufacturing process (S200). In an example embodiment, the in-situ pre-cleaning process may be performed when the manufacturing process is an etching process.

In an example embodiment, the performing the in-situ pre-cleaning process (S100) may include cleaning the inside of the chamber 400 and forming a passivation layer 406 on an inner surface of the chamber 400. The cleaning the inside of the chamber 400 may include removing contaminants within the chamber 400. For example, the contaminants may include byproducts remaining within the chamber 400 after performing a previous manufacturing process. The contaminants may include a worn or lost passivation layer remaining on a wall of the chamber 400 after the previous manufacturing process.

The forming the passivation layer 406 on the inner surface of the chamber 400 may be performed after cleaning the inside of the chamber 400. For example, the passivation layer 406 may be formed on the inner surface of the chamber 400 by means of deposition. The passivation layer 406 may be formed on the chamber protective layer 404. Accordingly, the chamber protective layer 404 may protect the wall of the chamber 400, and the passivation layer 406 may protect the chamber protective layer 404. The passivation layer 406 may contribute to maintaining consistency within the chamber 400. For example, the passivation layer 406 may stabilize plasma generated in the chamber 400 during a manufacturing process. For example, the passivation layer 406 may be silicon dioxide (SiO₂).

The passivation layer 406 may also be formed on the stage 460. Hereinafter, the passivation layer formed on the stage 460 is referred to herein as a stage protective layer 462. The stage protective layer 462 may be for example, the same material as the passivation layer 406 formed at the same time.

In an example embodiment, when the manufacturing process is a deposition process, the performing the in-situ pre-cleaning process (S100) may be omitted. When the manufacturing process is the deposition process, the cleaning the inside of the chamber 400 may be performed, whereas the forming the passivation layer 406 on the inner surface of the chamber 400 may be omitted.

Referring to FIGS. 6, 9, and 10, after performing the in-situ pre-cleaning process (S100), the substrate 440 may be placed on the stage 460 in the chamber 400 (S200). In an example embodiment, the substrate 440 may be placed on the stage protective layer 462 formed on the stage 460. For example, the stage protective layer 462 may be placed between the substrate 440 and the stage 460. The stage 460 may support and fix the substrate 440.

When the manufacturing process is the etching process, the base layer 442 of the substrate 440 may be disposed on the stage protective layer 462, and the measurement target layer 444 may be disposed on the base layer 442. When the manufacturing process is a deposition process, the substrate 440 may include the base layer 442 but may not include the measurement target layer 444.

The performing the manufacturing process (S300) may be subsequent to the placing the substrate 440 on the stage 460 (S200). As described herein, the manufacturing process may be an etching process or a deposition process.

Referring to FIGS. 6 and 11 to 13, the radiating the first light by the first light emitting system (S400) may include radiating a first portion of the first light E1 to the substrate 440 through the first port 410 of the chamber 400 by the first light emitting system 100. For example, in operation S400, the first light E1 emitted from the first light source 110 may be split by the first splitter 120 into the first incident light I1 incident on the first port 410 and the first split light D1 incident on the spectrometer 500, the first incident light I1 may be incident on the substrate 440 through the first port 410, and the first split light D1 may be incident on the spectrometer 500.

The radiating the second light by the second light emitting system (S500) may include radiating a second portion of the second light E2 to the inner surface of the wall of the chamber 400 through the second port 420 of the chamber 400 by the second light emitting system 200. For example, in operation S500, the second light E2 emitted from the second light source 210 may be split by the second splitter 220 into the second incident light 12 incident on the second port 420 and the second split light D2 incident on the spectrometer 500, the second incident light 12 may be incident on the inner surface of the wall of the chamber 400 through the second port 420, and the second split light D2 may be incident on the spectrometer 500.

The receiving the lights by the spectrometer 500 (S600) may include receiving a substrate-reflected light R1 reflected from the substrate 440 and a wall-reflected light R2 reflected from the inner surface of the wall by the spectrometer 500. The receiving the lights by the spectrometer 500 (S600) may further include receiving a first split light D1 and a second split light D2. The substrate-reflected light R1 may include a first substrate-reflected light R11 reflected at an interface 442a between the base layer 442 and the measurement target layer 444, and the second substrate-reflected light R12 reflected from the surface 444a of the measurement target layer 444. The wall-reflected light R2 may include a first wall-reflected light R21 reflected at an interface 400a between the wall of the chamber 400 and the chamber protective layer 404, a second wall-reflected light R22 reflected at an interface 404a between the chamber protective layer 404 and the passivation layer 406, and a third wall-reflected light R23 reflected from a surface 406a of the passivation layer 406.

The calculating the thicknesses of the layers (S700) may include calculating a thickness t11 of the measurement target layer 444 by the spectrometer 500. For example, in the calculating the thicknesses of the layers (S700), the spectrometer 500 may calculate the thickness t11 of the measurement target layer 444 using the first substrate-reflected light R11, the second substrate-reflected light R12, and the first split light D1.

In addition, the calculating the thicknesses of the layers (S700) may include calculating a thickness t21 of the chamber protective layer 404 and a thickness t22 of the passivation layer 406 by the spectrometer 500. For example, in the calculating the thicknesses of the layers (S700), the spectrometer 500 may calculate the thickness t21 of the chamber protective layer 404 using the first wall-reflected light R21, the second wall-reflected light R22, and the second split light D2, and may calculate the thickness t22 of the passivation layer 406 using the second wall-reflected light R22, the third wall-reflected light R23, and the second split light D2. In an example embodiment, the thicknesses t11, t21, and t22 of the measurement target layer 444, the chamber protective layer 404, and the passivation layer 406 may be simultaneously calculated and measured.

In an example embodiment, the calculating the thicknesses of the layers (S700) may include simultaneously calculating the thicknesses t11, t21, and t22 of the measurement target layer 444, the chamber protective layer 404, and the passivation layer 406 by performing a Fourier transform on complex data of the received lights. For example, in operation S700, the spectrometer 500 may simultaneously calculate the thicknesses t11, t21, and t22 of the layers 444, 404, and 406 by performing a Fourier transform on complex data of the received substrate-reflected light R1, wall-reflected light R2, first split light D1, and second split light D2.

In an example embodiment, the radiating the first light by the first light emitting system (S400), the radiating the second light by the second light emitting system (S500), the receiving the lights by the spectrometer (S600), and the calculating the thicknesses of the layers (S700) may be followed by the performing the manufacturing process (S300). Thus, the thicknesses t21 and t22 of the chamber protective layer 404 and the passivation layer 406 and the thickness t11 of the measurement target layer 444 in the chamber 400 before the manufacturing process may be measured.

Alternatively, the radiating the first light by the first light emitting system (S400), the radiating the second light by the second light emitting system (S500), the receiving the lights by the spectrometer (S600), and the calculating the thicknesses of the layers (S700) may be performed in real time during the manufacturing process 300. As a result, changes in the thicknesses t21, t22, and t11 of the chamber protective layer 404, the passivation layer 406, and the measurement target layer 444 during the manufacturing process may be monitored in real time, which will be described in more detail with reference to FIGS. 14 and 15.

Alternatively, the radiating the first light by the first light emitting system (S400), the radiating the second light by the second light emitting system (S500), the receiving the lights by the spectrometer (S600), and the calculating the thicknesses of the layers (S700) may be followed by the performing the manufacturing process (S300) and may also be performed in real time during the performing the manufacturing process (S300). As a result, both initial values of the thicknesses t21, t22, and t11 of the chamber protective layer 404, the passivation layer 406, and the measurement target layer 444 and changes during the manufacturing process may be monitored.

In some embodiments, the radiating the second light by the second light emitting system (S500) may be performed independently of the radiating the first light by the first light emitting system (S400). For example, the radiating the second light by the second light emitting system (S500) may be performed before or after the radiating the first light by the first light emitting system (S400). Alternatively, the radiating the second light by the second light emitting system (S500) may be performed simultaneously with the radiating the first light by the first light emitting system (S400).

In an example embodiment, when the manufacturing process is the deposition process, the substrate 440 before the manufacturing process may not include the measurement target layer 444. The radiating the first light by the first light emitting system (S400) may be performed in real time during the performing the manufacturing process (S300).

In an example embodiment, the receiving the lights by the spectrometer (S600) may be performed simultaneously with the radiating the first light by the first light emitting system (S400). In an example embodiment, the receiving the lights by the spectrometer (S600) may be performed simultaneously with the radiating the second light by the second light emitting system (S500).

According to the above-described operating method, a change in state within the chamber 400 during the manufacturing process may be monitored in real time, and information on the monitored change may be provided to the operator. In addition, the manufacturing process may be controlled in response to the change in state within the chamber 400. Accordingly, a highly reliable product (for example, a semiconductor device, such as a semiconductor chip) may be manufactured. In addition, when the state within the chamber 400 during the manufacturing process is outside a certain level (e.g., a thickness of a substance on walls of the chamber 400 is above a certain level), the manufacturing process may be paused or stopped. For example, this pausing or stopping may be controlled automatically by a controller programmed to monitor the thickness of substances on the chamber walls, or may be controlled by an operator after a notification or other displayed information is generated to inform the operator of the state. Accordingly, contamination of the substrate 440 may be reduced, and manufacturing of defective products may be significantly reduced.

Hereinafter, a case in which the above-described operations S400, S500, S600, and S700 are performed in real-time during the performing the manufacturing process (S300) will be described in more detail with reference to FIGS. 14 and 15.

Referring to FIGS. 6, 14, and 15, when the manufacturing process is the etching process, plasma PL may be generated in the chamber 400 and on the substrate 440. The etching process may be performed using radicals and/or ions in the plasma PL. Byproducts may be generated in the chamber 400 during the etching process. The generated byproducts may adhere to the inner surface of the chamber 400. For example, a byproduct layer 408 may be formed on the passivation layer 406. The byproduct layer 408 may include etching byproducts.

As illustrated in FIG. 15, the second incident light 12 may be radiated toward the inner surface of the wall of the chamber 400, and a plurality of wall-reflected lights R21, R22, R23, and R24 may be generated. The plurality of wall-reflected lights R21, R22, R23, and R24 may include the first wall-reflected light R21 reflected at an interface 400a between the wall of the chamber 400 and the chamber protective layer 404, the second wall-reflected light R22 reflected at an interface 404a between the chamber protective layer 404 and the passivation layer 406, the third wall-reflected light R23 reflected at an interface 406a between the passivation layer 406 and the byproduct layer 408, and the fourth wall-reflected light R24 reflected from the surface 408a of the byproduct layer 408.

In the receiving the lights by the spectrometer (S600), the spectrometer 500 may receive the first to fourth wall-reflected lights R21, R22, R23, and R24, the first and second substrate-reflected lights R11 and R12, and the first and second split lights D1 and D2. In the calculating the thicknesses of the layers (S700), the spectrometer 500 may calculate a thickness t23 of the byproduct layer 408 using the third and fourth wall-reflected lights R23 and R24 and the second split light D2.

In FIGS. 14 and 15, the etching process has been described as an example of the manufacturing process. However, example embodiments are not limited thereto, and the operating method may be applied to other manufacturing processes. For example, when the manufacturing process is the deposition process, the byproduct layer 408 may be a residual deposition layer accumulated on the wall of the chamber 400. As a result, the thickness of the byproduct layer 408 formed during the manufacturing process may be measured in real time. In addition, a change in state within the chamber 400 during the process may be monitored in real time, and information on the monitored change may be provided to the operator. Furthermore, the manufacturing process may be controlled in response to the change in the state within the chamber 400 that occurred during the manufacturing process.

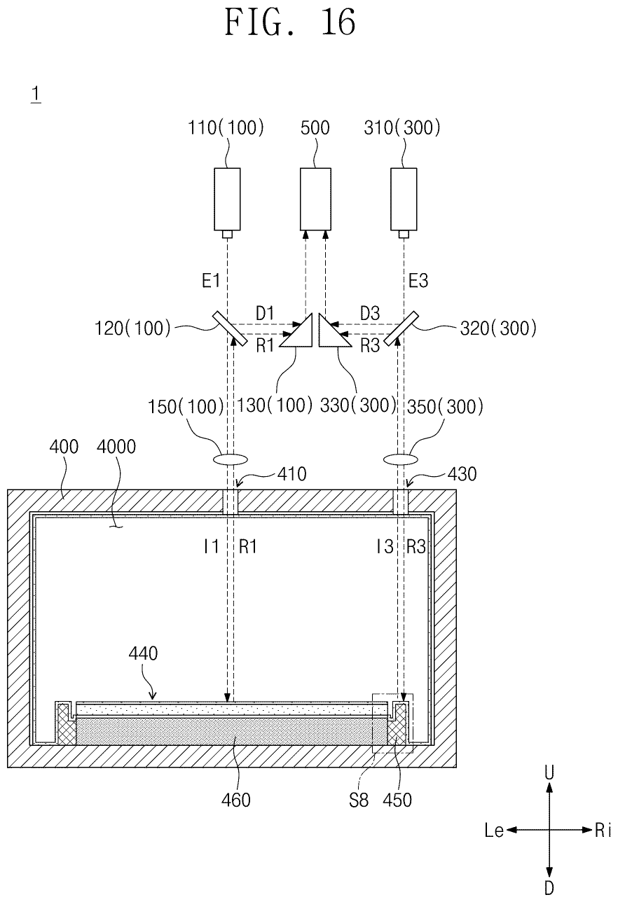

FIG. 16 is a diagram illustrating a substrate processing apparatus 1 according to an example embodiment.

Referring to FIG. 16, the substrate processing apparatus 1 according to the present embodiment may include an edge ring 450. The edge ring 450 may be disposed within a chamber 400 and may extend along the perimeter of a stage 460. For example, the edge ring 450 may surround the stage 460 in plan view. The edge ring 450 may extend along the perimeter of a substrate 440. The edge ring 450 may guide a substrate such that the substrate does not deviate from a desired horizontal location. In addition, the edge ring 450 may protect an edge of the substrate during a manufacturing process.

The chamber 400 may have a third port 430. In an example embodiment, the third port 430 may be formed in a ceiling of the chamber 400 and may be spaced apart from the first port 410. The location of the third port 430 is not limited thereto and may vary.

The substrate processing apparatus 1 may include a third light emitting system 300 configured to radiate light through the third port 430. The third light emitting system 300 may be configured to radiate third incident light 13 to the edge ring 450. For example, the third light emitting system 300 may be configured to vertically radiate the third incident light 13 to an upper surface of the edge ring 450. The third port 430 may be disposed over the edge ring 450.

The third light emitting system 300 may include a third light source 310, configured to emit the third light E3, and a third splitter 320 configured to split the third light E3. The third splitter 320 may split the third light E3 into a plurality of lights. For example, the third splitter 320 may split the third light E3 into the third incident light 13 incident on the third port 430 and the third split light D3 incident on the spectrometer 500.

The third light emitting system 300 may further include a third reflector 330 configured to guide the third split light D3 to the spectrometer 500. The third reflector 330 may be configured to change a propagation path of the third split light D3 emitted from the third splitter 320. For example, the third reflector 330 may be a mirror reflecting the third split light D3 to the spectrometer 500.

The third light emitting system 300 may further include a third condensing lens 350 configured to condense the third incident light 13 incident on the third port 430. The illuminance of the third incident light 13 incident on the third port 430 may be increased by the third condensing lens 350. The third condensing lens 350 may be located between the third splitter 320 and the third port 430.

The third light E3 may be emitted from the third light source 310 and may pass through the third splitter 320. The third splitter 320 may split the third light E3 into the third incident light 13 and the third split light D3. The third incident light 13 emitted from the third splitter 320 may be incident into the chamber 400 through the third condensing lens 350 and the third port 430.

The third incident light 13, which has passed through the third port 430, may be radiated to the edge ring 450. The third incident light 13 may be reflected from the edge ring 450. The light reflected from the edge ring 450 may be for example as a ring-reflected light R3 or a third reflected light (hereinafter, may be referred to as a “ring reflected light R3”). Hereinafter, for ease of description, the light reflected from the edge ring 450 may be for example, a ring-reflected light R3.

The ring-reflected light R3 may be emitted from the chamber 400 through the third port 430. The third condensing lens 350 may condense the ring-reflected light R3 emitted through the third port 430.

The ring-reflected light R3 may be incident on the third splitter 320, and the third splitter 320 may change a propagation path of the ring-reflected light R3. The third splitter 320 may guide the ring-reflected light R3 to the third reflector 330. For example, the third splitter 320 may reflect the ring-reflected light R3 to the third reflector 330.

The third reflector 330 may be configured to guide the ring-reflected light R3 to the spectrometer 500. For example, the third reflector 330 may reflect the ring-reflected light R3 to the spectrometer 500, and thus the ring-reflected light R3 may be incident on the spectrometer 500. In addition, as described herein, the third reflector 330 may reflect the third split light D3 to the spectrometer 500.

The spectrometer 500 may be configured to receive not only the first split light D1 and the substrate-reflected light R1, provided from the first light emitting system 100, but also the third split light D3 and the ring-reflected light R3 provided from the third light emitting system 300.

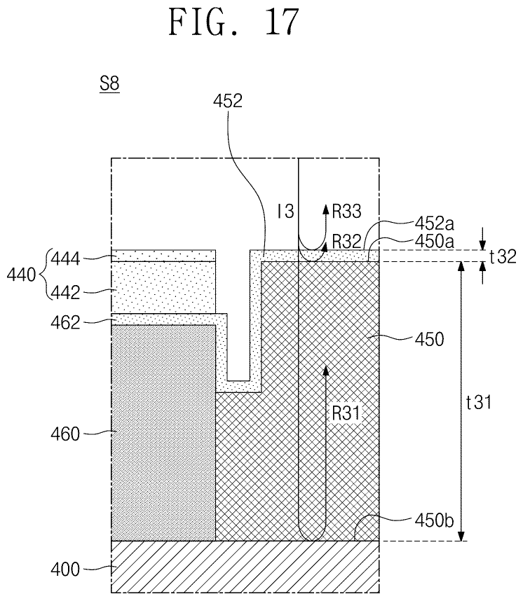

FIG. 17 is an enlarged view of region S8 of FIG. 16.

Referring to FIG. 17, in an example embodiment, the edge ring 450 may have a ring protective layer 452 formed on a surface (for example, an upper surface, or the like) of the edge ring 450. The ring protective layer 452 may correspond to a portion of the passivation layer 406 formed in the herein-described in-situ pre-cleaning process.

The third incident light 13 may be radiated to the ring protective layer 452 on the edge ring 450. A portion of the third incident light 13 may pass through the ring protective layer 452 and the edge ring 450. For example, the edge ring 450 may be metal or ceramic. The third light E3 emitted from the third light source 310 may be light in a wavelength band that may pass through the edge ring 450. For example, the third light E3 may be an X-ray or a gamma ray that may pass through the edge ring 450.

The third incident light 13, which has passed through the edge ring 450, may be reflected from a bottom surface 450b of the edge ring 450. For example, the third incident light 13, which has passed through the edge ring 450, may be reflected at an interface 450b between the chamber 400 and the edge ring 450. A light, reflected from a rear surface 450b of the edge ring 450, may be for example, a first ring-reflected light R31.

The first ring-reflected light R31 may pass through the edge ring 450 and the ring protective layer 452, and then be emitted into the processing space 4000. For example, the first ring-reflected light R31 may be reflected from the rear surface 450b of the edge ring 450, and then be emitted in a vertical direction.

Another portion of the third incident light 13, which has passed through the ring protective layer 452, may be reflected at an interface 450a between the edge ring 450 and the ring protective layer 452. A light, reflected at the interface 450a between the edge ring 450 and the ring protective layer 452, may be for example, a second ring-reflected light R32. The second ring-reflected light R32 may pass through the ring protective layer 452, and then be emitted into a processing space 4000. For example, the second ring-reflected light R32 may be reflected at the interface 450a between the edge ring 450 and the ring protective layer 452, and then be emitted in a vertical direction.

Another portion of the third incident light 13 may be reflected from the surface 452a of the ring protective layer 452. The light reflected from the surface 452a of the ring protective layer 452 may be for example, the third ring-reflected light R33. The third ring-reflected light R33 may be emitted from the surface 452a of the ring protective layer 452 into the processing space 4000. For example, the third ring-reflected light R33 may be reflected from the surface 452a of the ring protective layer 452, and then be emitted in a vertical direction.

The ring-reflected light R3 may include a first ring-reflected light R31, a second ring-reflected light R32, and a third ring-reflected light R33. Therefore, the spectrometer 500 may be configured to receive the first, second, and third ring-reflected lights R31, R32, and R33.

The spectrometer 500 may be configured to calculate a thickness t31 of the edge ring 450 and a thickness t32 of the ring protective layer 452 based on the received lights. For example, the spectrometer 500 may calculate the thickness t31 of the edge ring 450 based on the first ring-reflected light R31, the second ring-reflected light R32, and the third split light D3, and may calculate the thickness t32 of the ring protective layer 452 based on the second ring-reflected light R32, the third ring-reflected light R33, and the third split light D3. Accordingly, the substrate processing apparatus 1 may monitor the thickness t32 of the ring protective layer 452 and/or the thickness t31 of the edge ring 450.

The substrate processing apparatus 1 of FIGS. 16 and 17 may include the first light emitting system 100 and the third light emitting system 300. However, example embodiments are not limited thereto. In an example embodiment, the second light emitting system 200 of FIG. 1 or FIG. 5 may be applied to the substrate processing apparatus 1 of FIGS. 16 and 17. For example, the substrate processing apparatus 1 may include the first light emitting system 100, the second light emitting system 200, and the third light emitting system 300. The spectrometer 500 may receive the first to third split lights D1, D2, and D3, the substrate-reflected light R1, the wall-reflected light R2, and the ring-reflected light R3. In the substrate processing apparatus 1 according to an example embodiment, the spectrometer 500 and the second light emitting system 200 may be installed, and the first and third light emitting systems 100 and 300 may be omitted.

As set forth herein, a substrate processing apparatus according to an example embodiment and a method of operating the same may monitor a change on a wall of a chamber due to a spectrometer configured to receive a wall-reflected light.

In addition, the substrate processing apparatus according to example embodiments and a method of operating the same may measure a thickness of a remaining chamber protective layer in real time before or during a process due to a spectrometer configured to calculate a thickness of the chamber protective layer based on the received wall-reflected light.

In addition, the substrate processing apparatus according to example embodiments and a method of operating the same may measure a thickness of the measurement target layer in real time during a process due to a spectrometer configured to calculate the thickness of the measurement target layer based on a received substrate-reflected light.

In addition, the substrate processing apparatus according to example embodiments and a method of operating the same may simultaneously monitor a state of a substrate and a state of a wall of the chamber due to a single spectrometer configured to receive both a substrate-reflected light and a wall-reflected light.

In addition, the substrate processing apparatus according to example embodiments and a method of operating the same may simultaneously calculate the thickness of the measurement target layer and the thickness of the chamber protective layer by analyzing complex data of split light and reflected light, due to a spectrometer using Fourier transform.

In addition, the substrate processing apparatus according to example embodiments and a method of operating the same may measure the thickness of the remaining passivation layer in real time before or during a process due to a spectrometer configured to calculate the thickness of the passivation layer based on the received wall-reflected light. Thus, the completeness of an in-situ pre-cleaning process may be inspected.

In addition, the substrate processing apparatus according to example embodiments and a method of operating the same may measure a thickness of a byproduct layer, formed during a process, in real time due to a spectrometer configured to calculate the thickness of the byproduct layer based on the received wall-reflected light.

In addition, the substrate processing apparatus according to example embodiments and a method of operating the same may measure a thickness of the chamber protective layer, remaining on the wall of the chamber, to provide information on a replacement cycle of parts to an operator. Thus, unnecessary waste of parts may be significantly reduced, and costs of a manufacturing process may be reduced. Additionally, unnecessary manpower waste of operators may be reduced.

In addition, the substrate processing apparatus according to example embodiments and a method of operating the same may monitor a change in the chamber which occurs during a process, in real time and provide information on the monitored change to the operator.

In addition, the substrate processing apparatus according to example embodiments and a method of operating the same may control a process in response to a change in state within the chamber that occurred during the process. Thus, compensation based on the changes in the state within the chamber may be provided. Also, products having uniform quality may be manufactured.

In addition, the substrate processing apparatus according to example embodiments and a method of operating the same may stop a process when a state within a chamber is outside a certain level during the process. As a result, unnecessary contamination of the substrate may be reduced, and manufacturing of defective products may be significantly reduced.

While example embodiments have been shown and described herein, it will be apparent to those skilled in the art that modifications and variations could be made without departing from the scope of the present inventive concept.

What is claimed is:

1. A substrate processing apparatus comprising:
a chamber having a first port and a second port;
a stage disposed inside the chamber and configured to support a substrate;
a first light emitting system configured to radiate a first incident light through the first port onto the substrate when disposed inside the chamber;
a second light emitting system configured to radiate a second incident light through the second port onto an inner surface of a wall of the chamber; and
a spectrometer configured to receive a substrate-reflected light reflected from the substrate and a wall-reflected light reflected from the inner surface of the wall of the chamber.

2. The substrate processing apparatus of claim 1, wherein
the chamber comprises a chamber protective layer covering an inner surface of the chamber, and
the spectrometer is configured to receive a first wall-reflected light, reflected from an interface between the wall and the chamber protective layer, and a second wall-reflected light, reflected from a surface of the chamber protective layer, and is further configured to calculate a measurement value of a thickness of the chamber protective layer based on the received first and second wall-reflected lights.

3. The substrate processing apparatus of claim 2, wherein
the substrate comprises:
a base layer; and
a measurement target layer disposed on the base layer, and
the spectrometer is configured to receive a first substrate-reflected light, reflected from an interface between the base layer and the measurement target layer, and a second substrate-reflected light, reflected from an upper surface of the measurement target layer, and is further configured to calculate a measurement value of a thickness of the measurement target layer based on the received first and second substrate-reflected lights.

4. The substrate processing apparatus of claim 3, wherein
the spectrometer is configured to simultaneously calculate the thickness of the measurement target layer and the thickness of the chamber protective layer using a Fourier transform.

5. The substrate processing apparatus of claim 2, wherein
the spectrometer is configured to receive the second wall-reflected light, reflected from an interface between the chamber protective layer and a passivation layer, and a third wall-reflected light, reflected from a surface of the passivation layer, and is further configured to calculate a thickness of the passivation layer based on the received second and third wall-reflected lights.

6. The substrate processing apparatus of claim 5, wherein
the chamber protective layer includes yttrium oxide (Y₂O₃), and
the passivation layer includes silicon dioxide (SiO₂).

7. The substrate processing apparatus of claim 5, wherein
the spectrometer is configured to further receive a third wall-reflected light, reflected from an interface between the passivation layer and a byproduct layer formed on the passivation layer, and a fourth wall-reflected light, reflected from a surface of the byproduct layer, and is further configured to calculate a thickness of the byproduct layer based on the received third and fourth wall-reflected lights.

8. The substrate processing apparatus of claim 1, wherein
the first light emitting system comprises:
a first light source configured to emit a first light; and
a first splitter configured to split the first light into the first incident light, incident on the first port, and a first split light incident on the spectrometer.

9. The substrate processing apparatus of claim 1, wherein
the second light emitting system comprises:
a second light source configured to emit a second light; and
a second splitter configured to split the second light into the second incident light, incident on the second port, and a second split light incident on the spectrometer.

10. A substrate processing apparatus comprising:
a chamber having a port formed in a first wall of the chamber;
a stage disposed inside the chamber and configured to support a substrate;
a light source configured to emit a light;
a splitter configured to split the light into a split light and an incident light incident on an inner surface of a second wall of the chamber through the port; and
a spectrometer configured to receive the split light and a wall-reflected light reflected from the inner surface of the second wall of the chamber,
wherein
the first wall of the chamber opposes the second wall of the chamber.

11. The substrate processing apparatus of claim 10, wherein
the chamber comprises a chamber protective layer covering an inner surface of the second wall of the chamber, and
the spectrometer is configured to receive a first wall-reflected light, reflected from an interface between the second wall of the chamber and the chamber protective layer, and a second wall-reflected light, reflected from a surface of the chamber protective layer, and is further configured to calculate a thickness of the chamber protective layer based on the received first and second wall-reflected lights.

12. The substrate processing apparatus of claim 11, further comprising:
a passivation layer disposed on the chamber protective layer.

13. The substrate processing apparatus of claim 12, wherein
the spectrometer is configured to receive the second wall-reflected light, reflected from an interface between the chamber protective layer and the passivation layer, and a third wall-reflected light, reflected from a surface of the passivation layer, and is further configured to calculate a thickness of the passivation layer based on the received second and third wall-reflected lights.

14. The substrate processing apparatus of claim 11, wherein
a byproduct layer is on the chamber protective layer, and
the spectrometer is further configured to receive a third wall-reflected light, reflected from an interface between the chamber protective layer and the byproduct layer, and a fourth wall-reflected light, reflected from a surface of the byproduct layer, and is further configured to calculate a thickness of the byproduct layer based on the received third and fourth wall-reflected lights.

15. A method of operating a substrate processing apparatus, the method comprising:
placing a substrate on a stage inside a chamber;
performing a manufacturing process on the substrate;
radiating a first portion of a first light onto the substrate through a first port of the chamber by a first light emitting system;
radiating a second portion of a second light onto an inner surface of a wall of the chamber through a second port of the chamber by a second light emitting system;
receiving a substrate-reflected light reflected from the substrate and a wall-reflected light reflected from the inner surface of the wall by a spectrometer; and
generating a thickness of a measurement target layer of the substrate and a thickness of a chamber protective layer on an inner surface of the wall based on the substrate-reflected light and wall-reflected light.

16. The method of claim 15, wherein
the radiating the first portion of the first light comprises splitting the first light into a first incident light, incident on the substrate through the first port, and a first split light incident on the spectrometer,
the radiating the second portion of the second light comprises splitting the second light into a second incident light, incident on the inner wall of the chamber through the second port, and a second split light incident on the spectrometer,
the spectrometer is configured to further receive the first split light incident on the spectrometer and the second split light incident on the spectrometer, and
the spectrometer is configured to simultaneously calculate the thickness of the measurement target layer and the thickness of the chamber protective layer by performing a Fourier transform on complex data of the substrate-reflected light, the wall-reflected light, the first split light, and the second split light.

17. The method of claim 15, further comprising:
performing an in-situ pre-cleaning process inside the chamber before placing the substrate on the stage,
wherein
a passivation layer is formed on the chamber protective layer by the in-situ pre-cleaning process,
the receiving the wall-reflected light comprises the spectrometer receiving a first wall-reflected light reflected from an interface between the wall of the chamber and the chamber protective layer, a second wall-reflected light reflected from an interface between the chamber protective layer and the passivation layer, and a third wall-reflected light reflected from a surface of the passivation layer, and the thickness of the chamber protective layer and a thickness of the passivation layer are calculated based on the received first to third wall-reflected lights.

18. The method of claim 17, wherein
a byproduct layer is formed on the passivation layer when the manufacturing process is performed, and
the receiving the wall-reflected light further comprises the spectrometer receiving the third wall-reflected light, reflected from an interface between the passivation layer and the byproduct layer, and a fourth wall-reflected light reflected from a surface of the byproduct layer, and
a thickness of the byproduct layer is calculated based on the received third and fourth wall-reflected lights.

19. The method of claim 17, wherein the receiving the substrate-reflected light and the wall-reflected light, and the generating the thicknesses of the measurement target layer of the substrate, the chamber protective layer, and the byproduct layer, is performed in real time during the manufacturing process.

20. The method of claim 15, wherein
the radiating the first portion of the first light, the radiating the second portion of the second light, the receiving the substrate-reflected light and the wall-reflected light, and the generating the thickness of the measurement target layer and the thickness of the chamber protective layer are performed before performing the manufacturing process.
